(19) United States
(12) Patent Application Publication
(10) Pub. No.: US 2024/0324140 A1
(43) Pub. Date: Sep. 26, 2024

(54) COOLING METHOD, ELECTRONIC DEVICE MANUFACTURING METHOD, AND COOLING DEVICE

(71) Applicant: Kioxia Corporation, Tokyo (JP)

(72) Inventors: Hiroto TAKAHASHI, Yokohama Kanagawa (JP); Koichi SATO, Yokohama Kanagawa (JP); Takeaki SERIZAWA, Yokohama Kanagawa (JP)

(73) Assignee: Kioxia Corporation, Tokyo (JP)

(21) Appl. No.: 18/591,258

(22) Filed: Feb. 29, 2024

(30) Foreign Application Priority Data
Mar. 20, 2023 (JP) 2023-043830

(51) Int. Cl. H05K 7/20

(52) U.S. Cl. CPC H05K 7/20272; H05K 7/20236

(57) ABSTRACT

A cooling method includes placing a container having thermal conductivity in a cooling tank configured to accommodate liquid refrigerant, accommodating an electronic device to be cooled in the container, and immersion cooling the container using the liquid refrigerant in a state where the electronic device remains separate from the liquid refrigerant.

### CROSS-REFERENCE TO RELATED APPLICATION

This application is based upon and claims the benefit of priority from Japanese Patent Application No. 2023-043830, filed Mar. 20, 2023, the entire contents of which are incorporated herein by reference.

### FIELD

Embodiments described herein relate generally to a cooling method, an electronic device manufacturing method, and a cooling device.

### BACKGROUND

Immersion cooling is known, in which an electronic device is directly cooled using liquid refrigerant by immersing the electronic device in the liquid refrigerant.

### DESCRIPTION OF THE DRAWINGS

FIG. 1 is a perspective view for illustrating a cooling device of a first embodiment.

FIG. 2 is a diagram showing an example of an electronic device of the first embodiment.

FIG. 3 is a cross-sectional view for illustrating the cooling device of the first embodiment.

FIG. 4 is a plan view showing an example of a fixing member of the first embodiment.

FIGS. 5A and 5B are cross-sectional views for illustrating movement of an upper opening/closing portion of the first embodiment.

FIGS. 6A and 6B are cross-sectional views for illustrating movement of a lower fixing portion of the first embodiment.

FIG. 7 is a flowchart showing a test method of the first embodiment.

FIG. 8 is a flowchart showing a manufacturing method of the first embodiment.

FIG. 9 is a flowchart showing a test method of a second embodiment.

FIG. 10 is a cross-sectional view for illustrating a cooling device of a third embodiment.

FIG. 11 is a cross-sectional view for illustrating a cooling device of a modification example of the third embodiment.

FIG. 12 is a perspective view for illustrating a position regulating unit of a first modification example of the embodiment.

FIG. 13 is a perspective view for illustrating a position regulating unit of a second modification example of the embodiment.

FIG. 14 is a perspective view for illustrating a cooling device of a third modification example of the embodiment.

FIG. 15 is a perspective view for illustrating a position regulating unit of the third modification example of the embodiment.

FIG. 16 is a cross-sectional view for illustrating a cooling device of a fourth modification example of the embodiment.

FIG. 17 is a perspective view for illustrating a box member of a fifth modification example of the embodiment.

### DETAILED DESCRIPTION

Embodiments provide a cooling method, an electronic device manufacturing method, and a cooling device that can improve workability regarding cooling post-processing.

In general, according to at least one embodiment, there is provided a cooling method including placing a container having thermal conductivity in a cooling tank configured to accommodate liquid refrigerant, accommodating an electronic device to be cooled in the container, and immersion cooling the container using the liquid refrigerant in a state where the electronic device remains separate from the liquid refrigerant.

Hereinafter, a cooling method, an electronic device manufacturing method, and a cooling device according to embodiments will be described with reference to the drawings. In the following description, components having the same or similar functions are denoted by the same reference numerals. Further, redundant descriptions of these components may be omitted.

In the embodiments, terms are defined as follows. “Parallel”, “orthogonal”, or “same” may respectively include “substantially parallel”, “substantially orthogonal”, or “substantially the same”. “Connection” is not limited to mechanical connection, but may include electrical connection. In other words, “connection” is not limited to a case where two elements to be connected are directly connected, but may also include a case where two elements to be connected are connected with another element interposed between them. Also, “connection” is not limited to a state of being coupled, but may also correspond to a state of just touching.

X direction, Y direction, and Z direction are defined as follows. The X direction and the Y direction are horizontal directions. The X direction is a direction in which support frames 44A and 44B, which will be described below, are movable. The Y direction is a direction that intersects (for example, is orthogonal to) the X direction. The Y direction is, for example, a direction in which a pair of horizontal frames 42A and 42B, which will be described below, are spaced apart. The Z direction is a direction that intersects (for example, is orthogonal to) the X direction and the Y direction. The Z direction is, for example, a vertical direction.

### First Embodiment

### 1. Overall Configuration

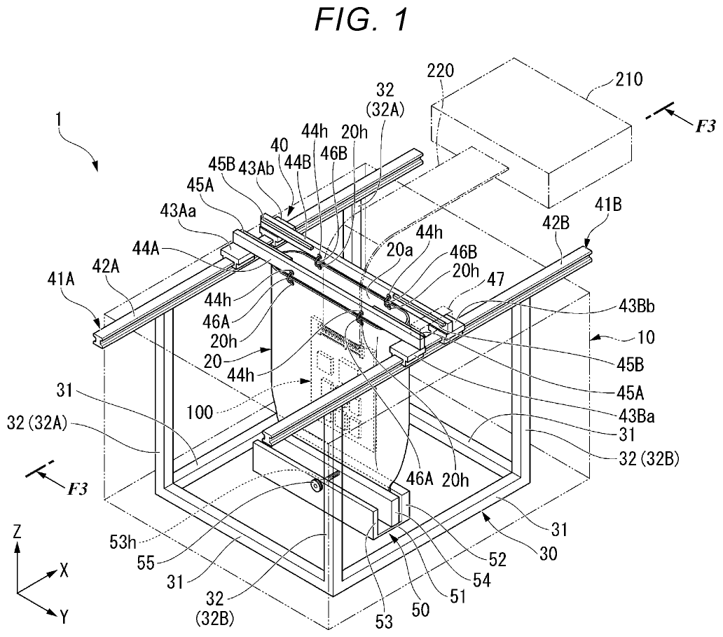

FIG. 1 is a perspective view for illustrating a cooling device 1 of a first embodiment. The cooling device 1 is a cooling device that uses immersion cooling, and is capable of cooling an electronic device 100 that is to be cooled. The electronic device 100 is, for example, a semiconductor storage device. The cooling device 1 is used, for example, in one or more tests of manufacturing processing of the electronic device 100. The cooling device 1 is not limited to a cooling device used in testing the electronic device 100, but may be a cooling device used when the electronic device 100 is used. Further, the electronic device 100 to be cooled is not limited to the semiconductor storage device, and may be any other type of electronic device as appropriate.

### Electronic Device to be Cooled

First, an example of the electronic device 100 to be cooled will be described.

The electronic device 100 is, for example, the semiconductor storage device such as a Solid State Drive (SSD). The electronic device 100 is attached to an information processing device such as a server or a personal computer, and is used as a storage device of the information processing device. In the embodiments, the information processing device to which the electronic device 100 is connected during use is referred to as a “host device”.

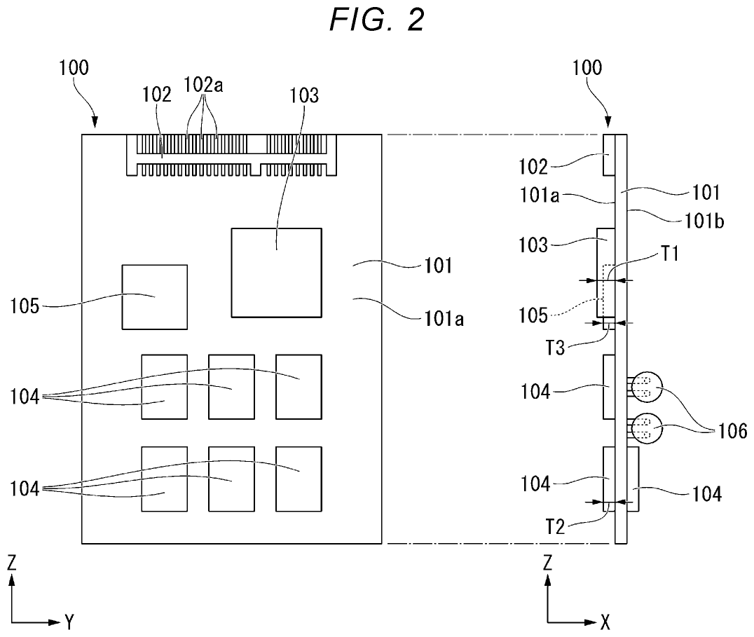

FIG. 2 is a diagram showing an example of the electronic device 100. The electronic device 100 includes, for example, a substrate 101, a connector 102, a controller 103, a plurality of NAND memories 104, a Dynamic Random Access Memory (DRAM) 105, and a plurality of capacitors 106.

The substrate 101 is a printed circuit board. The substrate 101 has an insulating base material and a wiring pattern provided on the insulating base material. The substrate 101 has a plate shape along the Y direction and the Z direction. The substrate 101 has a first surface 101a and a second surface 101b located on an opposite side to the first surface 101a.

The connector 102 is an electrical connection unit connectable to the host device. The connector 102 is provided at an end of the substrate 101. The connector 102 has a plurality of terminals 102a located in the Y direction. The connector 102 is, for example, a board-to-board connector (BtoB connector). For example, a flat cable extending from the host device can be connected to the connector 102.

The controller 103 is a control component mounted or attached to the substrate 101. The controller 103 controls the entire electronic device 100 in an integrated manner. The controller 103 is, for example, a semiconductor package configured as a System on a Chip (SoC) in which a host interface circuit that communicates with the host device, a control circuit that controls the plurality of NAND memories 104, a control circuit that controls the DRAM 105, and the like are integrated into one semiconductor chip. That is, the controller 103 is a circuit device. The controller 103 is mounted on the first surface 101a of the substrate 101, for example. The controller 103 is a component that generates heat when the electronic device 100 is used. In this embodiment, the controller 103 generates the largest amount of heat when the electronic device 100 is in use among the plurality of components mounted on the substrate 101.

The NAND memory 104 is a semiconductor package that includes a semiconductor memory chip that stores data in a non-volatile manner. The NAND memory 104 is, for example, a NAND flash memory. That is, the NAND memory 104 is a circuit device. For example, the plurality of NAND memories 104 are mounted separately on the first surface 101a and the second surface 101b of the substrate 101. The NAND memory 104 is a component that generates heat when the electronic device 100 is in use. The NAND memory 104 is an example of a “semiconductor memory”. However, the “semiconductor memory” is not limited to the NAND flash memory, and may be other types of memory such as a NOR memory, a Magnetoresistive Random Access Memory (MRAM), or resistance change memory.

The DRAM 105 is a semiconductor package that has a semiconductor memory chip that stores data in a volatile manner. That is, the DRAM 105 is a circuit device. The DRAM 105 is used as a data buffer in which write data received from the host device, read data read from one or more NAND memories 104, and the like are temporarily stored. The DRAM 105 is mounted on the first surface 101a of the substrate 101, for example. The DRAM 105 is a component that generates heat when the electronic device 100 is in use.

The capacitor 106 has a power backup function for the purpose of data protection in the event of an unexpected power cut to the electronic device 100. For example, when the power supply from the host device is unexpectedly cut off, the capacitor 106 supplies power to the controller 103, the plurality of NAND memories 104, and the DRAM 105 for a certain period of time. The capacitor 106 is, for example, an electrolytic capacitor. The capacitor 106 is mounted on the second surface 101b of the substrate 101, for example.

As shown in FIG. 2, in a thickness direction (X direction) of the substrate 101, a thickness T1 of the controller 103 is larger than a thickness T2 of the NAND memory 104 and larger than a thickness T3 of the DRAM 105. Further, unlike the controller 103, the capacitor 106 is mounted on the second surface 101b of the substrate 101. Therefore, on the first surface 101a of the substrate 101, the controller 103 has the maximum thickness (maximum component height).

### 2. Cooling Device Configuration

Next, returning to FIG. 1, the configuration of the cooling device 1 will be described. The cooling device 1 using single-phase immersion cooling will be described below. However, the cooling device 1 may be a cooling device using multiphase immersion cooling. The cooling device 1 includes, for example, a cooling tank 10, a sleeve 20, a main frame 30, an upper opening/closing portion 40, and a lower fixing portion 50. In this embodiment, the upper opening/closing portion 40 and the lower fixing portion 50 form an example of a “holding unit”.

### 2.1 Cooling Tank

First, the cooling tank 10 will be described.

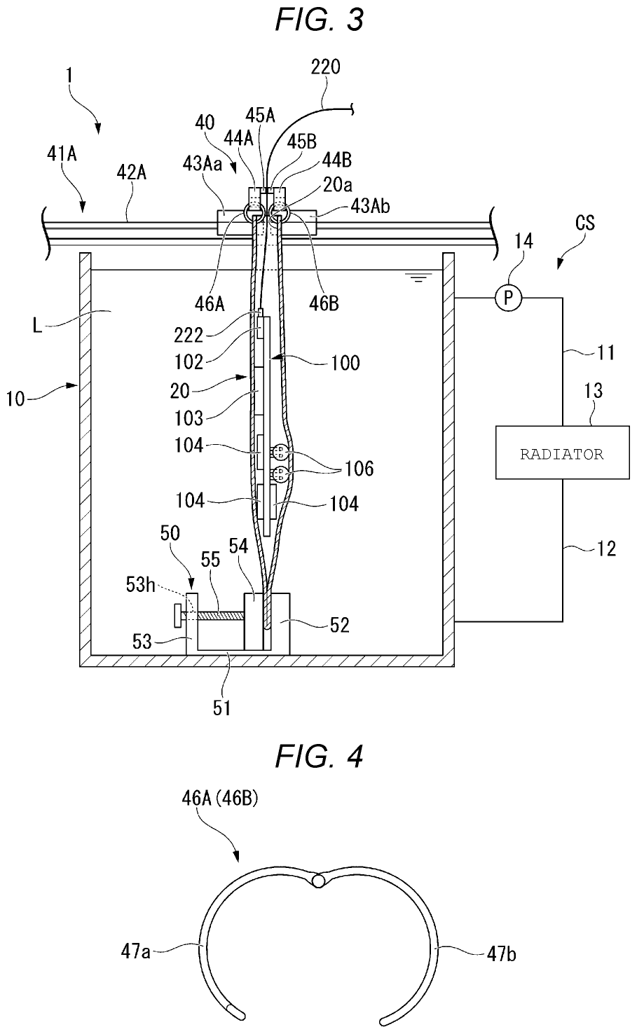

The cooling tank 10 is a tank body that can be used for immersion cooling, and is capable of accommodating liquid refrigerant L (see FIG. 3). The liquid refrigerant L is, for example, inert liquid having insulating properties, such as distilled water (purified water), a fluorine-based inert liquid, or silicone oil. However, the liquid refrigerant L is not limited to the above example, and may be a conductive liquid, such as industrial water.

FIG. 3 is a cross-sectional view for illustrating the cooling device 1, and is a cross-sectional view taken along a line F3-F3 in FIG. 1. For example, a cooling system CS that cools the liquid refrigerant L is connected to the cooling tank 10. The cooling system CS includes a first pipe 11, a second pipe 12, a radiator 13, and a pump 14.

One end of the first pipe 11 is connected to an upper part of the cooling tank 10. The other end of the first pipe 11 is connected to the radiator 13. One end of the second pipe 12 is connected to the radiator 13. The other end of the second pipe 12 is connected to a lower part of the cooling tank 10. The pump 14 is provided in the middle of the first pipe 11 or the second pipe 12. When the pump 14 is driven, the liquid refrigerant L located in the upper part of the cooling tank 10 flows into the radiator 13 through the first pipe 11 and is cooled by passing through the radiator 13. The liquid refrigerant L cooled by passing through the radiator 13 is returned to the lower part of the cooling tank 10 through the second pipe 12.

The radiator 13 may be a heat sink having a plurality of fins, or may be a heat exchanger that cools the liquid refrigerant L through heat exchange between the liquid refrigerant L and other cooling water. Further, when the cooling device 1 is an apparatus that uses multiphase immersion cooling, the cooling system CS has a cooler that cools the gas phase refrigerant and returns it to the liquid refrigerant L.

### 2.2 Sleeve

Next, the sleeve 20 will be described.

As shown in FIG. 3, the sleeve 20 is a member that is placed in the cooling tank 10 and accommodates the electronic device 100 to be cooled. The sleeve 20 is, for example, a bag member having an open upper end and liquid-tightly closed ends (for example, the lower end and both side ends) other than the upper end. The upper end of the sleeve 20 has an opening 20a. The electronic device 100 can be inserted into the sleeve 20 through the opening 20a. The sleeve 20 is an example of a “container”.

The electronic device 100 is accommodated in the sleeve 20 while being connected to a test device 210 (see FIG. 1) via a flat cable 220, for example. The flat cable 220 is, for example, a flexible flat cable. With the electronic device 100 accommodated in the sleeve 20, the flat cable 220 extends from the inside of the sleeve 20 to the outside of the sleeve 20 through the opening 20a of the sleeve 20. The flat cable 220 has a connector 222 that is capable of fitting into the connector 102 of the electronic device 100. For example, the electronic device 100 is supported by the flat cable 220 by fitting the connector 102 of the electronic device 100 with the connector 222 of the flat cable 220, and its position in the Y direction and the Z direction is regulated.

The sleeve 20 has thermal conductivity and can conduct heat between the inside and the outside of the sleeve 20. The sleeve 20 transfers heat generated by the electronic device 100 accommodated in the sleeve 20 to the liquid refrigerant L in the cooling tank 10 by thermal conduction. As a result, the sleeve 20 is cooled by immersion cooling using the liquid refrigerant L, so that the electronic device 100 can be cooled while the electronic device 100 is not in contact with the liquid refrigerant L.

The sleeve 20 is formed of, for example, a thermally conductive film. The material of the sleeve 20 is, for example, polyimide, but is not limited thereto. The heat dissipation performance, material, and the like of the sleeve 20 are not limited as long as it can cool the electronic device 100.

In this embodiment, the sleeve 20 has flexibility. At least a part of the sleeve 20 is deformed to follow the outer shape of the electronic device 100 and is in direct contact with (directly connected to) components (for example, the controller 103, the NAND memory 104, and the DRAM 105) in the electronic device 100. For example, when the sleeve 20 is placed in the liquid refrigerant L, the sleeve 20 is deformed to follow the outer shape of the electronic device 100 due to the hydraulic pressure of the liquid refrigerant L. For example, the sleeve 20 is deformed to follow the outer shape of the electronic device 100 by forcing a part of the air in the sleeve 20 to the outside of the sleeve 20 through the opening 20a due to the hydraulic pressure of the liquid refrigerant L.

In this embodiment, the sleeve 20 deforms to follow the outer shape of the electronic device 100 and is directly in contact with a plurality of components (for example, two or more components among the controller 103, the NAND memory 104, and the DRAM 105) in the electronic device 100. The sleeve 20 is in contact with the controller 103 having the maximum component height at least on the first surface 101a of the substrate 101.

In the embodiments, “deforming to follow the outer shape of the electronic device” means deforming so as to conform to the outer shape of the electronic device 100, for example (in other words, the sleeve 20 deforms along the surface of each of a plurality of components in the electronic device 100.) However, in the embodiments, “deformation to follow the outer shape of the electronic device” is not limited to large deformation to conform to the outer shape of the electronic device 100, and may also include minimal deformation of the sleeve 20 so that a part of the electronic device 100 and the sleeve 20 come into contact with each other.

In this embodiment, the upper end of the sleeve 20 is held by the upper opening/closing portion 40 (holding portion), which will be described below. For example, the upper end of the sleeve 20 has a plurality of holes 20h (see FIG. 1). A plurality of fixing members 46A and 46B, which will be described below, are respectively attached to the plurality of holes 20h.

### 2.3 Main Frame

Returning to FIG. 1, the main frame 30 will be described.

The main frame 30 is a base that supports the upper opening/closing portion 40, which will be described below. The main frame 30 may be provided in the cooling tank 10 or may be provided outside the cooling tank 10. The main frame 30 includes, for example, a plurality of lower frames 31 and a plurality of vertical frames 32. The plurality of lower frames 31 are located horizontally and extend in the X direction or the Y direction. The vertical frames 32 are connected to the lower frames 31, stand up from the lower frames 31, and extend in the vertical direction (Z direction).

The plurality of vertical frames 32 include, for example, a plurality of vertical frames 32A and a plurality of vertical frames 32B. The plurality of vertical frames 32A are located at a distance from each other in the X direction. The plurality of vertical frames 32B are spaced apart from the plurality of vertical frames 32A in the Y direction. The plurality of vertical frames 32B are located at a distance from each other in the X direction.

### 2.4 Upper Opening/Closing Portion

The upper opening/closing portion 40 is a mechanism for opening and closing the opening 20a of the sleeve 20. The upper opening/closing portion 40 includes, for example, a pair of linear guides 41A and 41B, a pair of support frames 44A and 44B, a plurality of elastic members 45A and 45B, and the plurality of fixing members 46A and 46B.

The linear guide 41A includes the horizontal frame 42A and movable bodies 43Aa and 43Ab. The horizontal frame 42A is located horizontally and extends in the X direction. The horizontal frame 42A is supported by the plurality of vertical frames 32A. Each of the movable bodies 43Aa and 43Ab is attached to the horizontal frame 42A, and is capable of sliding movement in the X direction along the horizontal frame 42A.

The linear guide 41B includes the horizontal frame 42B and movable bodies 43Ba and 43Bb. The horizontal frame 42B is located horizontally and extends in the X direction. The horizontal frame 42B is spaced apart from the horizontal frame 42A in the Y direction. The horizontal frame 42B is supported by the plurality of vertical frames 32B. Each of the movable bodies 43Ba and 43Bb is attached to the horizontal frame 42B and can slide along the horizontal frame 42B in the X direction.

The support frame 44A is located horizontally and extends in the Y direction. The support frame 44A is attached to the movable bodies 43Aa and 43Ba. Thereby, the support frame 44A can slide in the X direction as the movable bodies 43Aa and 43Ba move along the horizontal frames 42A and 42B, respectively. The support frame 44A has a plurality of holes 44h. The plurality of holes 44h are provided at positions spaced apart from each other in the Y direction. The plurality of fixing members 46A, which will be described below, are respectively attached to the plurality of holes 44h. Hereinafter, the support frame 44A will be referred to as a “first support frame 44A”.

The support frame 44B is located horizontally and extends in the Y direction. The support frame 44B is aligned in the X direction with respect to the support frame 44A. The support frame 44B is located parallel to the support frame 44A. The support frame 44B is attached to the movable bodies 43Ab and 43Bb. The support frame 44B can slide in the X direction by moving the movable bodies 43Ab and 43Bb along the horizontal frames 42A and 42B, respectively. The support frame 44B has the plurality of holes 44h. The plurality of holes 44h are provided at positions spaced apart from each other in the Y direction. The plurality of fixing members 46B, which will be described below, are respectively attached to the plurality of holes 44h. In the following, the support frame 44B will be referred to as a “second support frame 44B”.

The plurality of elastic members 45A are attached to the side surface of the first support frame 44A that faces the second support frame 44B. Each elastic member 45A is, for example, a rubber cushion member. For example, the plurality of elastic members 45A are located to avoid areas overlapping with the flat cable 220.

The plurality of elastic members 45B are attached to the side surface of the second support frame 44B that faces the first support frame 44A. Each elastic member 45B is, for example, a rubber cushion member. For example, the plurality of elastic members 45B are located to avoid areas overlapping with the flat cable 220.

The fixing member 46A is a member that fixes the first support frame 44A and the sleeve 20.

FIG. 4 is a plan view showing an example of the fixing member 46A. In this embodiment, the fixing member 46A includes a first member 47a and a second member 47b each formed in an arc shape. The fixing member 46A is deformable between a first state in which the first member 47a and the second member 47b are connected in an annular shape, and a second state in which one end of the first member 47a and one end of the second member 47b are separated from each other. In the second state, the other end of the first member 47a and the other end of the second member 47b are connected.

As shown in FIG. 1, the plurality of fixing members 46A fix the first support frame 44A and a part of the upper end of the sleeve 20. For example, the fixing member 46A is passed through the hole 20h of the sleeve 20 and the hole 44h of the first support frame 44A while being deformed to the second state. Then, by deforming the fixing member 46A to the first state, the first support frame 44A and the part of the upper end of the sleeve 20 are fixed.

The fixing member 46B is a member that fixes the second support frame 44B and the sleeve 20. In this embodiment, the fixing member 46B includes the first member 47a and the second member 47b each formed in an arc shape, similarly to the fixing member 46A. The fixing member 46B is deformable between a first state in which the first member 47a and the second member 47b are connected in an annular shape, and a second state in which one end of the first member 47a and one end of the second member 47b are separated from each other. In the second state, the other end of the first member 47a and the other end of the second member 47b are connected.

The plurality of fixing members 46B fix the second support frame 44B and another portion of the upper end of the sleeve 20. For example, the fixing member 46B is passed through the hole 20h of the sleeve 20 and the hole 44h of the second support frame 44B while being deformed to the second state. Then, by deforming the fixing member 46B to the first state, the second support frame 44B and another portion of the upper end of the sleeve 20 are fixed.

The method for fixing the upper end of the sleeve 20 to the support frames 44A and 44B is not limited to the above method. For example, the upper end of the sleeve 20 may be fixed to the support frames 44A and 44B by fixing members such as clips, hooks, pins, or screws. Further, the upper end of the sleeve 20 may be adhesively fixed to the support frames 44A and 44B using an adhesive, or may be welded and fixed to the support frames 44A and 44B by heating.

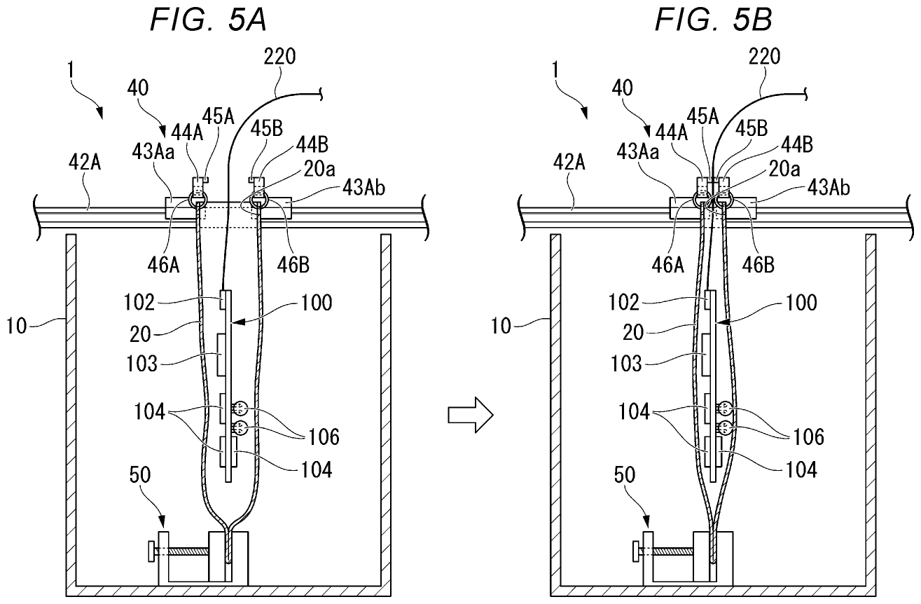

FIG. 5 is a cross-sectional view for illustrating the movement of the upper opening/closing portion 40. FIG. 5A shows a state in which the opening 20a of the sleeve 20 is opened by the upper opening/closing portion 40. FIG. 5B shows a state in which the opening 20a of the sleeve 20 is closed by the upper opening/closing portion 40. “Closing the opening” in the embodiments is not limited to a case where the opening is completely closed, but may also apply to a case where at least a part of the opening (opening 20a) is closed. In the embodiments, “closing the opening” may also apply to a case where the opening 20a is closed so as to leave a gap for air in the sleeve 20 to escape to the outside. In the embodiments, “closing the opening” means, for example, that the size of the opening 20a is reduced to such an extent that the electronic device 100 cannot be taken out through the opening 20a of the sleeve 20. The opening 20a of the sleeve 20 may be closed tightly.

In this embodiment, the opening 20a of the sleeve 20 is opened by moving the first support frame 44A and the second support frame 44B away from each other. On the other hand, the opening 20a of the sleeve 20 is closed by moving the first support frame 44A and the second support frame 44B toward each other. As a result, the opening 20a of the sleeve 20 is opened and closed while the sleeve 20 is placed in the cooling tank 10.

In addition, the upper opening/closing portion 40 may have a locking mechanism 47 (see FIG. 1) that restricts movement of the first support frame 44A and the second support frame 44B with the opening 20a of the sleeve 20 being closed. By fixing the positions of the first support frame 44A and the second support frame 44B by the locking mechanism 47, the shape of the sleeve 20 is maintained with the opening 20a of the sleeve 20 being closed. The number of locking mechanisms 47 is not limited to one, but may be two or more.

### 2.5 Lower Fixing Portion

Returning to FIG. 1, the lower fixing portion 50 will be described.

The lower fixing portion 50 regulates the position of a lower end of the sleeve 20 in the cooling tank 10 by fixing the lower end of the sleeve 20. The lower fixing portion 50 is an example of a “position regulating portion”. In this embodiment, the lower fixing portion 50 is provided at the bottom of the cooling tank 10. The lower fixing portion 50 has, for example, a base portion 51, a first standing portion 52, a second standing portion 53, a third standing portion 54, and a feed screw 55.

The base portion 51 is located horizontally along the bottom of the cooling tank 10. The first standing portion 52 is formed integrally with the base portion 51 and stands upward from the base portion 51. The second standing portion 53 is formed integrally with the base portion 51 and stands upward from the base portion 51. The second standing portion 53 is spaced apart from the first standing portion 52 in the X direction. The second standing portion 53 has a hole 53h into which the feed screw 55, which will be described below, engages.

The third standing portion 54 is located between the first standing portion 52 and the second standing portion 53. The third standing portion 54 is not fixed to the base portion 51 and is slidable along an upper surface of the base portion 51 in the X direction. The lower end of the sleeve 20 is disposed between the first standing portion 52 and the third standing portion 54. The feed screw 55 engages with the hole 53h of the second standing portion 53 and passes through the hole 53h. The tip of the feed screw 55 is rotatably fixed to a bearing (not illustrated) provided on the third standing portion 54.

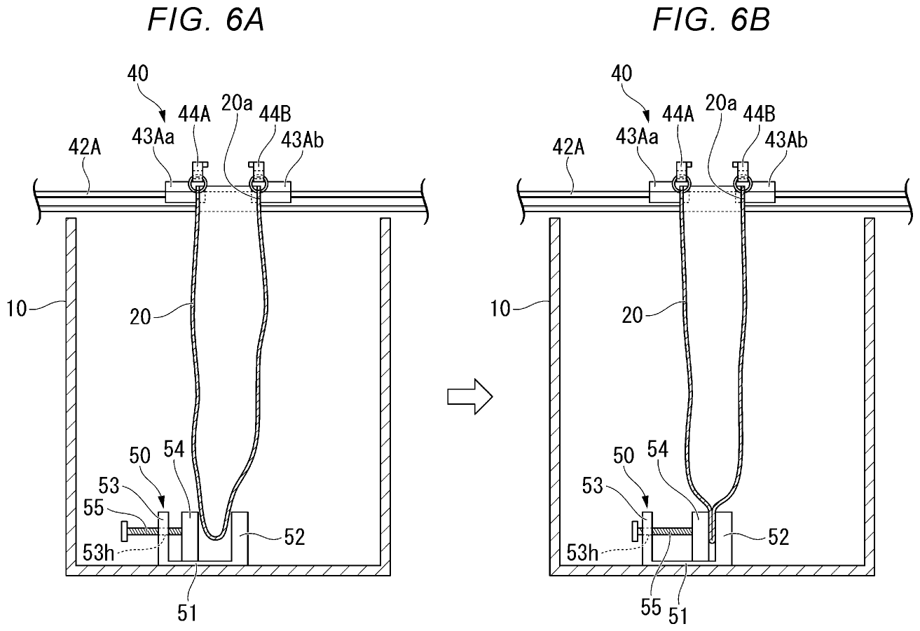

FIGS. 6A and 6B are cross-sectional views for illustrating movement of the lower fixing portion 50. FIG. 6A shows a state before the lower fixing portion 50 fixes the lower end of the sleeve 20. FIG. 6B shows a state in which the lower fixing portion 50 fixes the lower end of the sleeve 20.

In this embodiment, the third standing portion 54 moves toward the first standing portion 52 by rotating the feed screw 55 in a predetermined rotation direction. Thereby, the lower end of the sleeve 20 is fixed by being pinched between the first standing portion 52 and the third standing portion 54. On the other hand, by rotating the feed screw 55 in a direction opposite to the predetermined rotation direction, the third standing portion 54 is separated from the first standing portion 52. As a result, the lower end of the sleeve 20 is released from between the first standing portion 52 and the third standing portion 54.

### 3. Test Method for Electronic Device

Next, a method for testing the electronic device 100 using the cooling device 1 will be described.

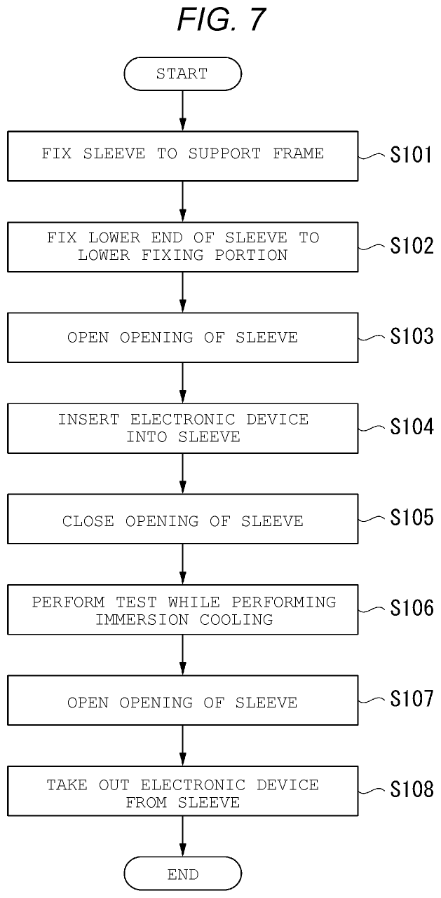

FIG. 7 is a flowchart showing the test method of the first embodiment. In this embodiment, before the electronic device 100 is accommodated in the sleeve 20, the sleeve 20 is fixed to the support frames 44A and 44B (S101). For example, the fixing members 46A and 46B are passed through the plurality of holes 20h of the sleeve 20, and are also passed through the plurality of holes 44h of the support frames 44A and 44B. Thereby, the upper end of the sleeve 20 is fixed to the support frames 44A and 44B.

Next, the lower end of the sleeve 20 is fixed by the lower fixing portion 50 (S102). For example, by inserting the lower end of the sleeve 20 between the first standing portion 52 and the third standing portion 54 of the lower fixing portion 50 and rotating the feed screw 55 in the predetermined rotation direction, the lower end portion of the sleeve 20 is pinched between the first standing portion 52 and the third standing portion 54. Thereby, the lower end of the sleeve 20 is fixed by the lower fixing portion 50.

Next, the liquid refrigerant L is supplied to the cooling tank 10, and the cooling tank 10 is filled with the liquid refrigerant L. The operation of supplying the liquid refrigerant L to the cooling tank 10 may be performed before the operation of S101 or S102, or after the operation of S104 or S105, which will be described below.

Next, the opening 20a of the sleeve 20 is opened using the upper opening/closing portion 40 (S103). For example, the opening 20a of the sleeve 20 is opened by moving the first support frame 44A and the second support frame 44B away from each other.

Next, the electronic device 100 is inserted into the sleeve 20 through the opening 20a of the sleeve 20 (S104). For example, the electronic device 100 is inserted into the sleeve 20 with the electronic device 100 and the cable 220 connected first. Alternatively, the electronic device 100 may be inserted into the sleeve 20 before the electronic device 100 and the cable 220 are connected. In this case, the electronic device 100 and the cable 220 are connected with the electronic device 100 being accommodated in the sleeve 20.

Next, the opening 20a of the sleeve 20 is closed using the upper opening/closing portion 40 (S105). For example, the opening 20a of the sleeve 20 is closed by moving the first support frame 44A and the second support frame 44B toward each other. When the locking mechanism 47 is provided, the positions of the first support frame 44A and the second support frame 44B may be fixed by the locking mechanism 47 so that the opening 20a of the sleeve 20 does not open during the test.

Next, the electronic device 100 is tested using the test device 210 while performing immersion cooling (S106). That is, the electronic device 100 connected to the test device 210 via the cable 220 is tested while the sleeve 20 is cooled by immersion cooling using the liquid refrigerant L and while the electronic device 100 is not in contact with the liquid refrigerant L. The test for the electronic device 100 is, for example, a function test for testing the function of the electronic device 100 or a thermal cycle test for testing the heat resistance of the electronic device 100. However, the test content of the electronic device 100 is not limited to the above example.

Next, after the test is finished, the opening 20a of the sleeve 20 is opened using the upper opening/closing portion 40 (S107). For example, the opening 20a of the sleeve 20 is opened by moving the first support frame 44A and the second support frame 44B away from each other.

Next, the electronic device 100 is taken out from inside the sleeve 20 through the opening 20a of the sleeve 20 (S108).

When testing another electronic device 100 subsequently, the sleeve 20 may remain in the cooling tank 10. That is, a test of another electronic device 100 is performed by omitting the processes from S101 to S103 described above.

### 4. Manufacturing Method of Electronic Device

Next, a method for manufacturing the electronic device 100 will be described.

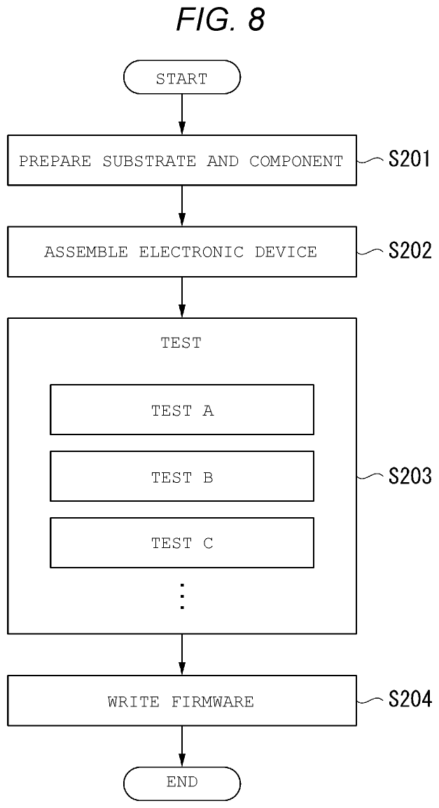

FIG. 8 is a flowchart showing a method for manufacturing the electronic device 100. First, the substrate 101 and various components (the controller 103, the plurality of NAND memories 104, the DRAM 105, and the like) to be mounted on the substrate 101 are prepared by being manufactured or procured (S201). Next, the electronic device 100 is assembled by mounting various components on the substrate 101 (S202).

Next, a test of the electronic device 100 is performed (S203). The test of the electronic device 100 includes, for example, a plurality of tests (test A, test B, test C, . . . ). A plurality of tests are performed using different cooling devices 1 and different test devices 210, for example. That is, the electronic device 100 is connected to the test device 210 of the test A, and inserted into the sleeve 20 placed in the cooling tank 10 of the test A, and the test A is performed. Next, the electronic device 100 is connected to the test device 210 of the test B and inserted into the sleeve 20 placed in the cooling tank 10 of the test B, and the test B is performed. Such operations are repeated as many times as there are tests.

Next, firmware for shipping is written into the electronic device 100 (S204). With this, the electronic device 100 is completed.

### 5. Advantages

As a comparative example, consider immersion cooling, in which an electronic device to be cooled is directly immersed in liquid refrigerant. In immersion cooling in this comparative example, in order to suppress the refrigerant that adheres to the electronic device during immersion cooling from mixing with liquid used in another process (for example, the liquid refrigerant used in immersion cooling during a testing process during manufacturing mixes with the liquid refrigerant used at a destination where the product is shipped), after immersion cooling, it is necessary to perform an operation for removing the refrigerant that is adhered to the electronic device. Further, in the immersion cooling of the comparative example, a drying process is required as a post-treatment every time immersion cooling is performed. As a result, the work becomes complicated and the manufacturing time of the electronic device increases due to addition of the drying process.

The cooling method of this embodiment includes locating the thermally conductive sleeve 20 in the cooling tank 10 capable of accommodating the liquid refrigerant L, accommodating the electronic device 100 to be cooled in the sleeve 20, and cooling the electronic device 100 in the sleeve 20 by immersion cooling using the liquid refrigerant L while the electronic device 100 is not in contact with the liquid refrigerant L. According to such a cooling method, since it is possible to suppress the liquid refrigerant L to adhere to the electronic device 100, it is possible to avoid the liquid refrigerant L to cool the electronic device 100 from mixing with liquid used in another process. Therefore, the work of removing the refrigerant adhering to the electronic device 100 becomes unnecessary, and thus it is possible to improve the workability regarding the cooling post-processing. Further, according to the cooling method of this embodiment, a drying processing after immersion cooling is not necessary. From this point of view as well, it is possible to improve the workability regarding cooling post-processing. As a result, the manufacturing time of the electronic device 100 can be shortened.

According to another viewpoint, according to the cooling method of the present embodiment, the electronic device 100 and the liquid refrigerant L are not in contact with each other, so that the degree of freedom of the refrigerant that can be used as the liquid refrigerant L increases. For example, it becomes possible to use low-cost, high-specific heat refrigerants such as water (for example, industrial water).

In this embodiment, the sleeve 20 has flexibility. According to such a configuration, it becomes easy to deal with the electronic devices 100 having various shapes. Thereby, the versatility of the cooling device 1 can be improved. Further, by deforming at least a part of the sleeve 20 to follow the outer shape of the electronic device 100, the heat of the electronic device 100 is easily transmitted to the liquid refrigerant L via the sleeve 20. Thereby, it is possible to improve cooling efficiency.

In this embodiment, the electronic device 100 includes the substrate 101 and components mounted on the substrate 101. At least a part of the sleeve 20 is deformed to follow the outer shape of the electronic device 100 and come into direct contact with (is connected to) the above-described components. According to such a configuration, the heat of the components mounted on the substrate 101 is easily transferred to the liquid refrigerant L via the sleeve 20. Thereby, it is possible to improve cooling efficiency.

In this embodiment, the sleeve 20 is placed in the cooling tank 10 before the electronic device 100 is accommodated in the sleeve 20. According to such a cooling method, since the sleeve 20 is placed in the cooling tank 10 in an empty state, workability regarding installation of the sleeve 20 can be improved. Further, when cooling a plurality of electronic devices 100 in sequence, there is no need to detach the sleeve 20 from the cooling tank 10 each time. Therefore, by replacing the electronic device 100 to be cooled with the sleeve 20 placed in the cooling tank 10, the plurality of electronic devices 100 can be cooled in sequence. Therefore, it is possible to further improve workability regarding cooling post-processing.

In this embodiment, the end of the sleeve 20 has the opening 20a. Immersion cooling is performed with the opening 20a of the sleeve 20 at least partially closed. After the immersion cooling is performed, the opening 20a of the sleeve 20 is opened, and the electronic device 100 is taken out from inside the sleeve 20. According to such a cooling method, the electronic device 100 can be cooled in a state where dust, dirt, and the like are difficult to enter in the sleeve 20.

In this embodiment, the opening 20a of the sleeve 20 is opened while the sleeve 20 is placed in the cooling tank 10. According to such a cooling method, when replacing the electronic device 100 to be cooled in the cooling device 1 equipped with the sleeve 20 in which the opening 20a is opened and closed, it becomes possible to replace the electronic device 100 with the sleeve 20 left in the cooling tank 10. Therefore, it is possible to further improve workability regarding cooling post-processing.

In this embodiment, the cooling device 1 has a holding portion (upper opening/closing portion 40, lower fixing portion 50). When the sleeve 20 is placed in the cooling tank 10, and the sleeve 20 is cooled by immersion cooling using the liquid refrigerant L while the electronic device 100 is not in contact with the liquid refrigerant L, the holding portion holds at least one of the upper and lower portions of the sleeve 20. According to such a configuration, the posture of the sleeve 20 is stabilized during immersion cooling. This makes it possible to prevent problems from occurring during testing or cooling.

### Second Embodiment

Next, a second embodiment will be described. The second embodiment differs from the t first embodiment in that the electronic device 100 is inserted into the sleeve 20 before the sleeve 20 is placed in the cooling tank 10. The configuration other than those described below is the same as the first embodiment.

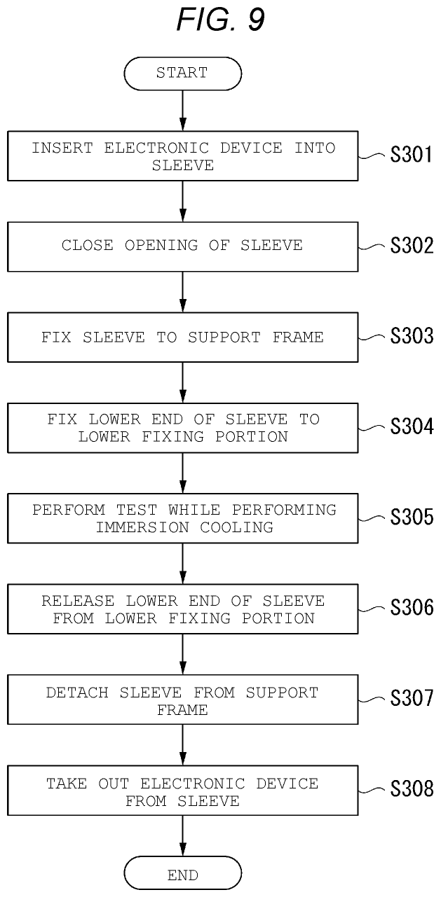

FIG. 9 is a flowchart showing a test method of the second embodiment. In this embodiment, before the sleeve 20 is placed in the cooling tank 10, the electronic device 100 is inserted into the sleeve 20 (S301). Next, the opening 20a of the sleeve 20 is closed (S302). In this embodiment, the sleeve 20 may be provided with an opening/closing mechanism (such as a fastener) that closes at least a part of the opening 20a.

Next, the sleeve 20 is fixed to the support frames 44A and 44B (S303). For example, the fixing members 46A and 46B are passed through the plurality of holes 20h of the sleeve 20, and are also passed through the plurality of holes 44h of the support frames 44A and 44B. Thereby, the sleeve 20 is fixed to the support frames 44A and 44B.

Next, the lower end of the sleeve 20 is fixed by the lower fixing portion 50 (S304). For example, by inserting the lower end of the sleeve 20 between the first standing portion 52 and the third standing portion 54 of the lower fixing portion 50 and rotating the feed screw 55 in the predetermined rotation direction, the lower end of the sleeve 20 is pinched between the first standing portion 52 and the third standing portion 54. Thereby, the lower end of the sleeve 20 is fixed by the lower fixing portion 50.

Next, the liquid refrigerant L is supplied to the cooling tank 10, and the cooling tank 10 is filled with the liquid refrigerant L. The operation of supplying the liquid refrigerant L to the cooling tank 10 may be performed before any of the operations from S301 to S304.

Next, a test of the electronic device 100 is performed using the test device 210 while performing immersion cooling (S305). That is, the electronic device 100 is tested while cooling the sleeve 20 by immersion cooling using the liquid refrigerant L in a state where the electronic device 100 is not in contact with the liquid refrigerant L.

Next, the lower end of the sleeve 20 is released from the lower fixing portion 50 (S306). For example, the third standing portion 54 is separated from the first standing portion 52 by rotating the feed screw 55 in the direction opposite to the predetermined rotation direction. Thereby, the lower end of the sleeve 20 is released from the lower fixing portion 50.

Next, the sleeve 20 is detach from the support frames 44A and 44B (S307). Next, the opening 20a of the sleeve 20 is opened, and the electronic device 100 is taken out from inside the sleeve 20 (S308).

According to such a cooling method, the electronic device 100 can be inserted into the sleeve 20 before the sleeve 20 is placed in the cooling tank 10. Therefore, even if the electronic device 100 has a complicated shape, it becomes easier to insert the electronic device 100 into the sleeve 20.

### Third Embodiment

Next, a third embodiment will be described. The third embodiment differs from the first embodiment in that an air adjusting system 60 that sucks air from inside the sleeve 20 is provided. The configuration other than those described below is the same as the first embodiment.

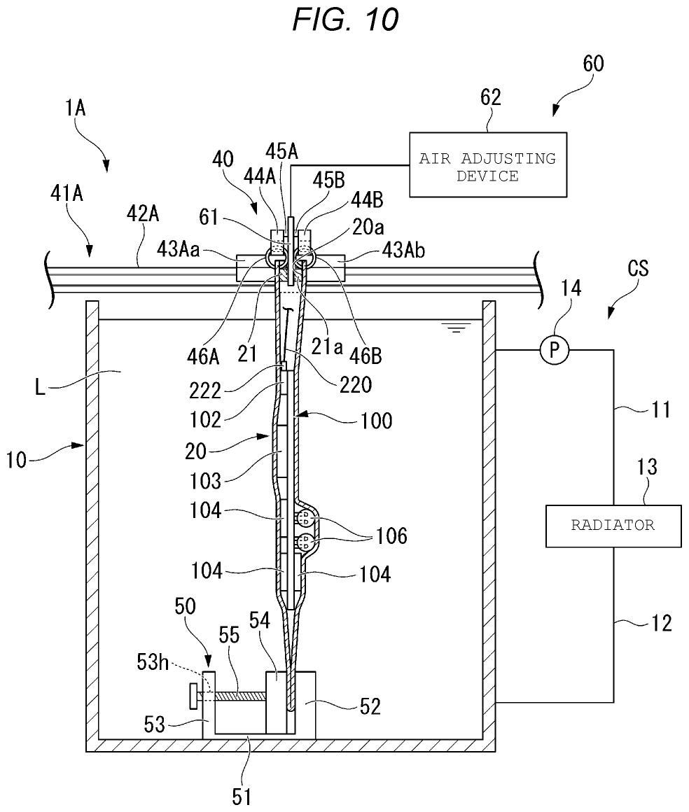

FIG. 10 is a cross-sectional view for illustrating a cooling device 1A of the third embodiment. In this embodiment, the cooling device 1A has the air adjusting system 60 in addition to the configuration of the cooling device 1 of the first embodiment. The air adjusting system 60 has, for example, a hose 61 and an air adjusting device 62.

The hose 61 is inserted from the outside of the sleeve 20 into the inside of the sleeve 20, for example through the opening 20a of the sleeve 20. The hose 61 is connected to the air adjusting device 62. In this embodiment, the sleeve 20 may have a sealing mechanism 21 that closes at least a part of the opening 20a when the hose 61 is inserted. The sealing mechanism 21 includes, for example, an elastic body 21a provided on an inner peripheral surface of the opening 20a.

The air adjusting device 62 is a device that can suck and inject air through the hose 61. For example, the air adjusting device 62 can suck air inside the sleeve 20 through the hose 61. Further, the air adjusting device 62 is capable of injecting air into the sleeve 20 through the hose 61. The air adjusting device 62 does not need to be a single device for suction and injection, and may separately include a suction device capable of suctioning air and an injection device capable of injecting air.

In this embodiment, after the electronic device 100 is accommodated in the sleeve 20 and the opening 20a of the sleeve 20 is closed (for example, after the opening 20a is closed and the opening 20a is sealed by the sealing mechanism 21), the air in the sleeve 20 is sucked by the air adjusting device 62. As a result, the pressure in the sleeve 20 is reduced, and the inner surface of the sleeve 20 comes into close contact with the electronic device 100 more easily than, for example, in the first embodiment. Thereby, immersion cooling to cool the sleeve 20 can be performed while the sleeve 20 and the electronic device 100 are in close contact with each other.

In this embodiment, air is injected into the sleeve 20 by the air adjusting device 62 after the immersion cooling is completed and before the electronic device 100 is taken out from the sleeve 20. This increases the pressure in the sleeve 20, making it easier to take out the electronic device 100 from the inside of the sleeve 20, compared to a case where the inside of the sleeve 20 remains depressurized.

According to such a configuration, since the adhesive property between the sleeve 20 and the electronic device 100 is increased compared to, for example, the first embodiment, it is possible to improve the cooling efficiency of the electronic device 100. Further, when air is injected into the sleeve 20 by the air adjusting device 62 after immersion cooling is completed, it becomes easier to take out the electronic device 100 from inside the sleeve 20.

The air adjusting device 62 may be a suction device that can only suck air instead of a device that can both suck and inject air. That is, air may be injected by a test operator manually opening the opening 20a of the sleeve 20.

### Modification Example of Third Embodiment

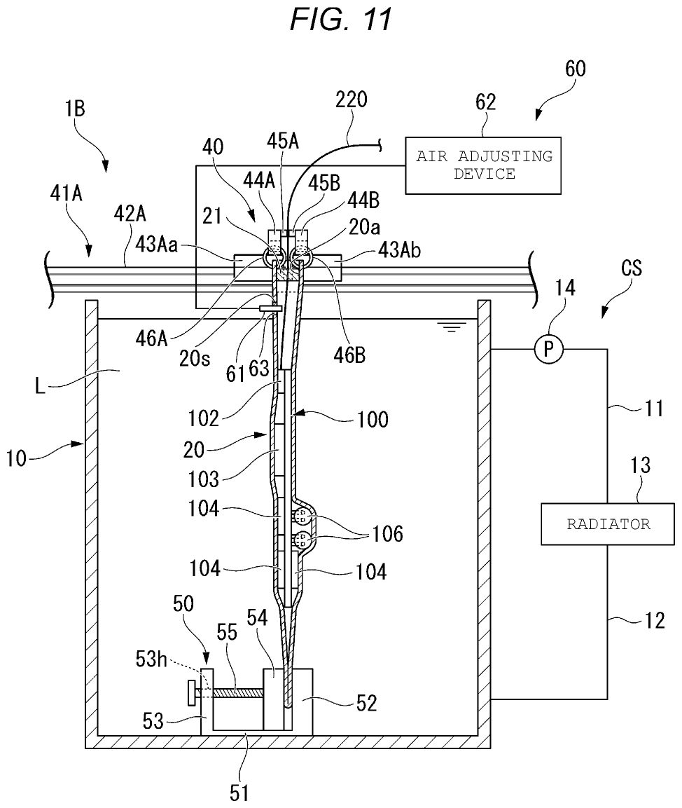

FIG. 11 is a cross-sectional view for illustrating a cooling device 1B of a modification example of the third embodiment. In this embodiment, the sleeve 20 has a hole 20s at a position different from the opening 20a. The hose 61 of the air adjusting system 60 is inserted into the hole 20s. A gap between the hole 20s and the hose 61 is closed with a closing member 63 such as insect rubber.

According to such a configuration, as in the third embodiment, it is possible to improve the cooling efficiency of the electronic device 100. Further, in this modification example, the sleeve 20 has the hole 20s into which the hose 61 is inserted, at a position different from the opening 20a. According to such a configuration, since the hose 61 is not present in the opening 20a of the sleeve 20, it becomes easier to keep the opening 20a airtight when closing the opening 20a. Further, according to the configuration of this modification example, the hose 61 can be attached to the sleeve 20 before the electronic device 100 is inserted into the sleeve 20. Thereby, work efficiency can be improved.

### Modification Examples of First to Third Embodiments

Next, modification examples applicable to the first to third embodiments will be described. In each modification example, the configurations other than those described below are the same as those in the first embodiment.

### First Modification Example

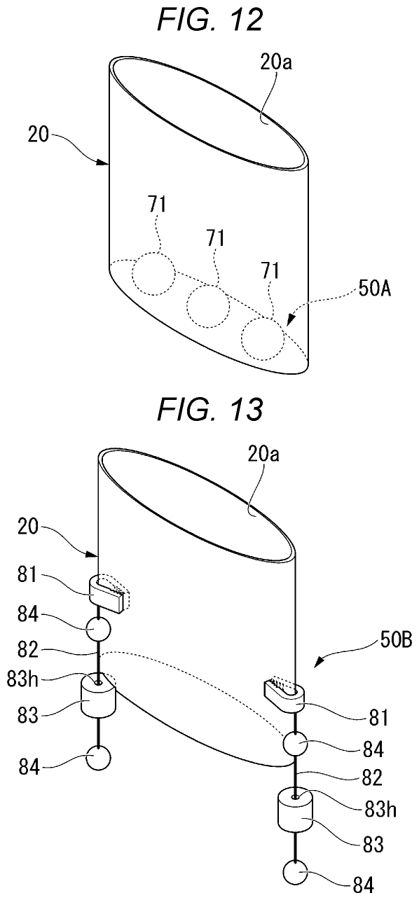

FIG. 12 is a perspective view for illustrating a position regulating portion 50A of a first modification example. The cooling device 1 of the first modification example includes the position regulating portion 50A instead of the lower fixing portion 50. The position regulating portion 50A includes, for example, one or more weights 71 placed in the lower end of the sleeve 20. The position regulating portion 50A regulates the position of the lower end of the sleeve 20 by the force of gravity acting on the weight 71.

According to such a configuration, the position of the lower end of the sleeve 20 can be regulated with a simpler configuration than in the first embodiment.

### Second Modification Example

FIG. 13 is a perspective view for illustrating a position regulating portion 50B of a second modification example. The cooling device 1 of the second modification example includes the position regulating portion 50B instead of the lower fixing portion 50. The position regulating portion 50B is, for example, a weight unit attached to an outer surface of the sleeve 20. The position regulating portion 50B includes, for example, an attachment portion 81, a connecting string 82, a weight 83, and a retaining portion 84.

The attachment portion 81 is attached to the outer surface of the sleeve 20. The attachment portion 81 is, for example, a clip that pinches the outer surface of the sleeve 20. The connecting string 82 is attached to the attachment portion 81. The weight 83 has an insertion hole 83h through which the connecting string 82 is passed. The retaining portions 84 are provided above and below the weight 83 in the connecting string 82. The provision of the retaining portion 84 prevents the weight 83 from coming off from the connecting string 82. The position regulating portion 50B regulates a position of the lower end of the sleeve 20 by the force of gravity acting on the weight 83.

According to such a configuration, the position of the lower end of the sleeve 20 can be regulated with a simpler configuration than in the first embodiment.

### Third Modification Example

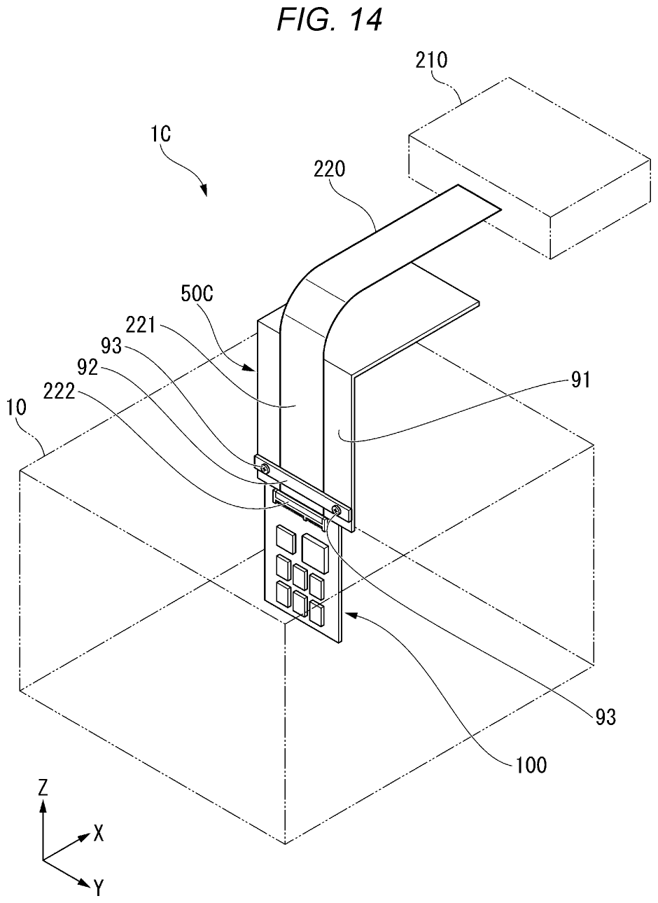

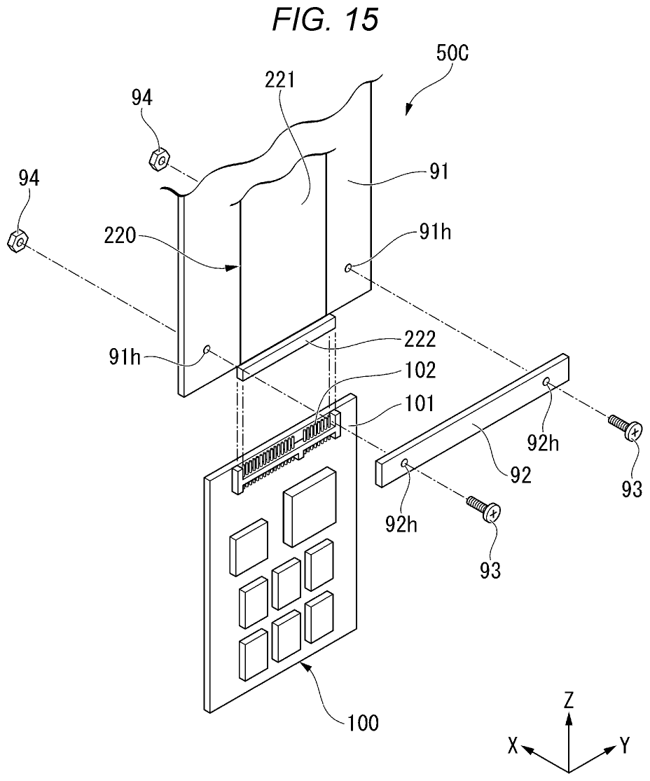

FIG. 14 is a perspective view for illustrating a cooling device 1C of a third modification example. In FIG. 14, for ease of understanding, configurations other than the cooling tank 10, a position regulating portion 50C, the electronic device 100, the flat cable 220, and the test device 210 are not illustrated.

The cooling device 1C of the third modification example includes the position regulating portion 50C instead of the lower fixing portion 50. The position regulating portion 50C regulates the position of the electronic device 100 by supporting the flat cable 220.

FIG. 15 is a perspective view for illustrating the position regulating portion 50C. The position regulating portion 50C includes, for example, a support plate 91, a fixing member 92, a plurality of fastening members 93, and a plurality of engagement members 94. Further, the flat cable 220 includes a wiring portion 221 and the connector 222. The connector 222 is provided at a tip of the wiring portion 221. The connector 222 is mated with the connector 102 of the electronic device 100.

The support plate 91 overlaps the wiring portion 221 of the flat cable 220. The support plate 91 includes a plate portion extending in the Y direction and the Z direction. The support plate 91 is made of metal, for example, and has higher rigidity than the flat cable 220. A width of the support plate 91 in the Y direction is wider than a width of the wiring portion 221 of the flat cable 220 in the Y direction, for example. The support plate 91 is fixed to the cooling tank 10, the main frame 30, the horizontal frames 42A and 42B, or the unillustrated casing of the cooling device 1, for example, via an unillustrated fixing member. The support plate 91 has a hole 91h through which the fastening member 93 is passed. The hole 91h penetrates the support plate 91 in the X direction.

The fixing member 92 is located to overlap the wiring portion 221 of the flat cable 220 from a side opposite to the support plate 91. The wiring portion 221 is interposed between the fixing member 92 and the support plate 91. The fixing member 92 is, for example, a fixing member for holding down a part of the wiring portion 221 of the flat cable 220. The fixing member 92 is a plate member or a block member. The fixing member 92 has a hole 92h through which the fastening member 93 is passed. The hole 92h passes through the fixing member 92 in the X direction. The fixing member 92 may be a block with a threaded hole in which a female thread is provided in the hole 92h.

Each fastening member 93 is passed through the hole 92h of the fixing member 92 and the hole 91h of the support plate 91. The engagement member 94 is engaged with a tip of the fastening member 93 that passes through the hole 92h of the fixing member 92 and the hole 91h of the support plate 91. The fastening member 93 is, for example, a screw. The engagement member 94 is, for example, a nut. The engagement member 94 is engaged with the tip of the fastening member 93, thereby the flat cable 220 and the support plate 91 are fixed.

According to the configuration of the third modification example, the position of the flat cable 220 is fixed between the support plate 91 and the fixing member 92. As a result, the position (for example, the position in the X direction) of the electronic device 100 fitted with the connector 222 is restricted.

According to such a configuration, the position of the sleeve 20 can be regulated with a simpler configuration than in the first embodiment.

### Fourth Modification Example

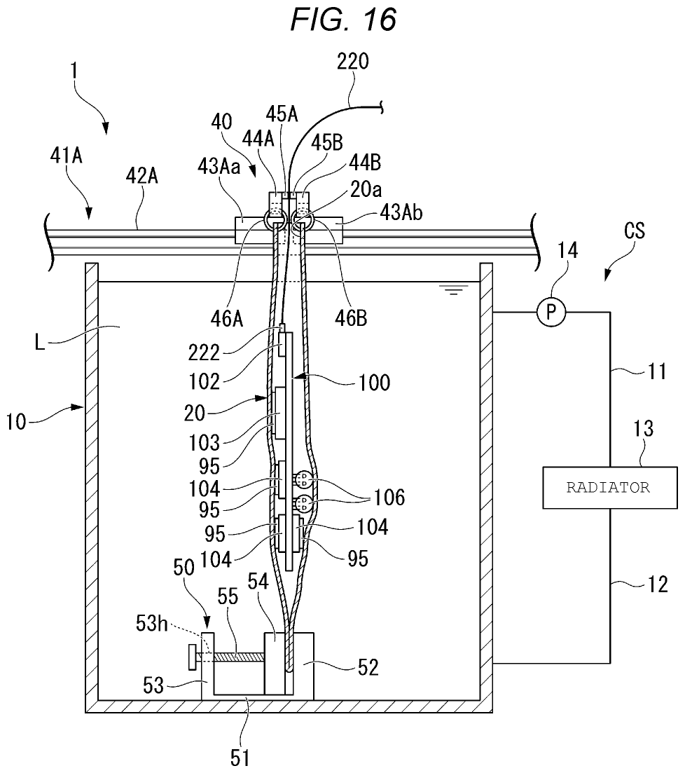

FIG. 16 is a cross-sectional view for illustrating the cooling device 1 of a fourth modification example. In the fourth modification example, heat conductive members 95 are attached to surfaces of a plurality of components in the electronic device 100. The sleeve 20 is connected to the plurality of components in the electronic device 100 via the heat conductive members 95. Such a configuration also allows heat generated by the components to be transferred to the liquid refrigerant L.

### Fifth Modification Example

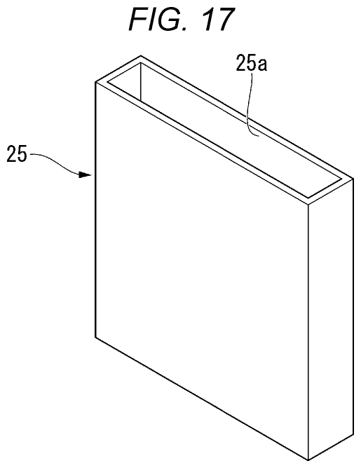

FIG. 17 is a perspective view for illustrating a box member 25 of a fifth modification example. The “container” in the embodiments is not limited to a flexible member. In this fifth modification example, the cooling device 1 has the box member 25 instead of the sleeve 20. The box member 25 is, for example, a metal box member having higher rigidity than the sleeve 20. For example, the box member 25 has an open upper end, and has ends (namely, a lower end and both side ends) other than the upper end closed in a liquid-tight manner. The upper end of the box member 25 has an opening 25a. The electronic device 100 (see FIG. 2) can be inserted into the box member 25 through the opening 25a. The box member 25 is an example of the “container”.

### Other Embodiments

Several embodiments and modification examples are described above. However, the embodiments and modification examples are not limited to the examples described above.

In the embodiments described above, both the first support frame 44A and the second support frame 44B are movable in the X direction. Alternatively, one of the first support frame 44A and the second support frame 44B may be fixed, and the opening 20a of the sleeve 20 may be opened and closed by moving the other in the X direction. Further, the linear guides 41A and 41B are not limited to those including a plurality of rolling elements, and may be simple guides. In the cooling device 1, instead of providing the upper opening/closing portion 40, the sleeve 20 may have an opening/closing mechanism such as a fastener.

According to at least one embodiment described above, the cooling method includes placing a container having thermal conductivity in a cooling tank that is capable of accommodating liquid refrigerant, accommodating an electronic device to be cooled in the container, and cooling the container by immersion cooling using the liquid refrigerant while the electronic device is not in contact with the liquid refrigerant. According to such a cooling method, workability can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A cooling method, comprising:
placing a container having thermal conductivity in a cooling tank configured to accommodate liquid refrigerant;
accommodating an electronic device to be cooled in the container; and
immersion cooling the container using liquid refrigerant in a state where the electronic device remains separate from the liquid refrigerant.

2. The cooling method according to claim 1, wherein
the container includes a sleeve that is flexible.

3. The cooling method according to claim 2, wherein
the electronic device includes a substrate and a component attached to the substrate, and
at least a part of the sleeve is deformed to follow an outer shape of the electronic device, and is connected to the component either directly or with a heat conductive member interposed between the sleeve and the component.

4. The cooling method according to claim 2, further comprising
deforming at least a part of the sleeve to follow an outer shape of the electronic device by sucking air in the sleeve using an air adjuster after the accommodating the electronic device in the container.

5. The cooling method according to claim 2 wherein the sleeve includes a thermally conductive film.

6. The cooling method according to claim 1, wherein
the placing the container in the cooling tank is performed before the accommodating the electronic device in the container.

7. The cooling method according to claim 1, wherein
the placing the container in the cooling tank is performed after the accommodating the electronic device in the container.

8. The cooling method according to claim 1, wherein
the container includes an opening,
the immersion cooling is performed with at least a part of the opening being closed, and
the cooling method further comprises opening the opening after the immersion cooling and removing the electronic device from an inside the container.

9. The cooling method according to claim 1, wherein
the immersion cooling is performed by regulating a position of a lower end of the container in the cooling tank.

10. The cooling method according to claim 1, where the electronic device includes a semiconductor storage device.

11. The cooling method according to claim 1, wherein the immersion cooling is one of single-phase immersion cooling and multiphase immersion cooling.

12. An electronic device manufacturing method, comprising:
placing a container having thermal conductivity in a cooling tank configured to accommodate liquid refrigerant;
accommodating an electronic device in the container, the electronic device being configured to be connected to a test device via a cable; and
testing the electronic device connected to the test device while immersion cooling the container using the liquid refrigerant in a state where the electronic device remains separate from the liquid refrigerant.

13. The electronic device manufacturing method according to claim 12, wherein
the container includes a sleeve that is flexible.

14. The electronic device manufacturing method according to claim 13, wherein
the electronic device includes a substrate and a component attached to the substrate, and
at least a part of the sleeve is deformed to follow an outer shape of the electronic device, and is connected to the component either directly or with a heat conductive member interposed between the sleeve and the component.

15. The electronic device manufacturing method according to claim 12, wherein
the placing the container in the cooling tank is performed before the accommodating the electronic device in the container.

16. The electronic device manufacturing method according to claim 12, wherein
the placing the container in the cooling tank is performed after the accommodating the electronic device in the container.

17. The electronic device manufacturing method according to claim 12, wherein
the container includes an opening,
the immersion cooling is performed with at least a part of the opening being closed, and
the cooling method further comprises opening the opening after the immersion cooling and removing the electronic device from an inside the container.

18. The electronic device manufacturing method according to claim 12, wherein
the immersion cooling is performed by regulating a position of a lower end of the container in the cooling tank.

19. The electronic device manufacturing method according to claim 12, where the electronic device includes a semiconductor storage device.

20. A cooling device, comprising:
a cooling tank configured to accommodate liquid refrigerant;
a container having a thermal conductivity and configured to accommodate an electronic device; and
a holder configured to hold at least one of an upper portion and a lower portion of the container in a state where the container accommodating the electronic device is placed in the cooling tank,
wherein the cooling tank is configured to immersion cool the container using the liquid refrigerant with the electronic device separated from the liquid refrigerant.
